(19) United States
(12) Patent Application Publication
(10) Pub. No.: US 2009/0039532 A1
(43) Pub. Date: Feb. 12, 2009

(54) SEMICONDUCTOR DEVICE PACKAGE HAVING A BACK SIDE PROTECTIVE SCHEME

(75) Inventors: Wen-Kun Yang, Hsin-Chu City (TW); Hsien-Wen Hsu, Lujhou City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/835,555

(22) Filed: Aug. 8, 2007

(51) Int. Cl. H01L 23/52; H01L 21/00; H01L 23/48; H01L 29/40

(52) U.S. Cl. 257/783; 257/691; 438/113; 257/E23.079; 257/E21.705

(57) ABSTRACT

The present invention provides a semiconductor device package, comprising a die having a back surface and an active surface formed thereon; an adhesive layer formed on the back surface of the die; a protection substrate formed on the adhesive layer; and a plurality of bumps formed on the active surface of the die for electrically connection. The present invention further provides a method for forming a semiconductor device package, comprising providing a plurality of die having a back surface and an active surface on a wafer; forming an adhesive layer on the back surface of the die; forming a protection substrates on the adhesive layer; forming a plurality of bumps on the active surface of each die; and dicing the plurality of die into individual die for singulation.

### FIELD OF THE INVENTION

This invention relates to a structure of semiconductor device package, and more particularly to a structure of semiconductor device package having a back side protective scheme, thereby protecting the package body and improving the reliability.

### BACKGROUND OF THE INVENTION

### Description of the Prior Art

In recent years, the high-technology electronics manufacturing industries launch more feature-packed and humanized electronic products. Rapid development of semiconductor technology has led to rapid progress of a reduction in size of semiconductor packages, the adoption of multi-pin, the adoption of fine pitch, the minimization of electronic components and the like.

Because conventional package technologies have to divide a dice on a wafer into respective dice and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip ball grid array (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dice). By wafer level packaging technology, we can produce die with extremely small dimensions and good electrical properties. Though the advantages of WLP technique mentioned above, some issues still exist influencing the acceptance of WLP technique. Traditionally, due to the package structure having multiple-chips is required, the sizes of the package structure increases with the numbers or total heights of multiple dice, so that the processes is more complex.

FIG. 1 illustrates the cross-section diagram of the conventional package with bottom surface protective coating disclosed by the U.S. patent application Ser. No. 6,023,094 and 6,175,162. The package structure 200 comprises a die 102 having a bottom surface 104 and a top surface 108. The package structure 200 further comprises a protective film 210 formed on the bottom surface 104 of the die 102 to cover the bottom surface 104, and a plurality of bumps 106 formed on the top surface 104 of the die 102. Further, the size of the protective film 210 is as same as the size of the chip 102. The protective film 210 has low thermal conductivity around 0.2, and the thickness is approximately 1.5-5 mils. Accordingly, the size of the package structure 200 is accumulated and equivalent to the total sizes of each material layer, and the differences of the thermal conductivity among each material layer are remarkable for poor adhesion among the material layers.

Further, the material of the protective film 210 usually includes the epoxy or rubber materials. When the epoxy material is employed for the protective film 210, in order to offer proper protection, the epoxy must be thick than others due to the material property. However, the protective film 210 will be too thick to warp during the manufacture process and it is very easy cracked during dicing saw or outside force. If the rubber material is employed for the protective film 210, the hardness of the protective film 210 is usually insufficient to protect the package structure. However, the processes for manufacturing the package structure also become more and more complex and costly. In conclusion, the thickness or hardness of the protective film 210 is serious concern and it is insufficient to protect the package structure at present.

In view of the aforementioned, what is required is a brand new scheme to overcome the above drawback.

### SUMMARY OF THE INVENTION

The present invention will descript some preferred embodiments. However, it is appreciated that the present invention can extensively perform in other embodiments except for these detailed descriptions. The scope of the present invention is not limited to these embodiments and should be accorded the following claims.

One objective of the present invention is to provide a structure of semiconductor device package having a back side protective scheme, which can protect the package structure from the external force.

Another objective of the present invention is to provide a structure of semiconductor device package having a back side protective scheme, which solves the crack and warp issues during process.

Still another objective of the present invention is to provide a structure of semiconductor device package having a back side protective scheme, which can lower the costs and improve the reliability.

Yet another objective of the present invention is to provide a structure of semiconductor device package having a back side protective scheme, which can easily perform the laser marking on the top surface of the semiconductor device package.

The present invention provides a structure of semiconductor device package, comprising a die having a back surface and an active surface formed thereon; an adhesive layer formed on the back surface of the die; a protection substrate formed on the adhesive layer; and a plurality of bumps formed on the active surface of the die for electrically connection.

The present invention provides a method for forming a structure of semiconductor device package, comprising providing a plurality of die having a back surface and an active surface on a wafer; forming an adhesive layer on the back surface of the die; forming a protection substrates on the adhesive layer; forming a plurality of bumps on the active surface of each die; and dicing the plurality of die into individual die for singulation.

### BRIEF DESCRIPTION OF THE DRAWINGS

The foregoing aspects and many of the attendant advantages of this invention will become more readily appreciated as the same becomes better understood by reference to the following detailed description, taken in conjunction with the accompanying drawings, wherein:

FIG. 1 illustrates a cross-section diagram of a structure of semiconductor device package according to the prior art; and

FIG. 2 illustrates a cross-section diagram of a structure of semiconductor device package according to the present invention.

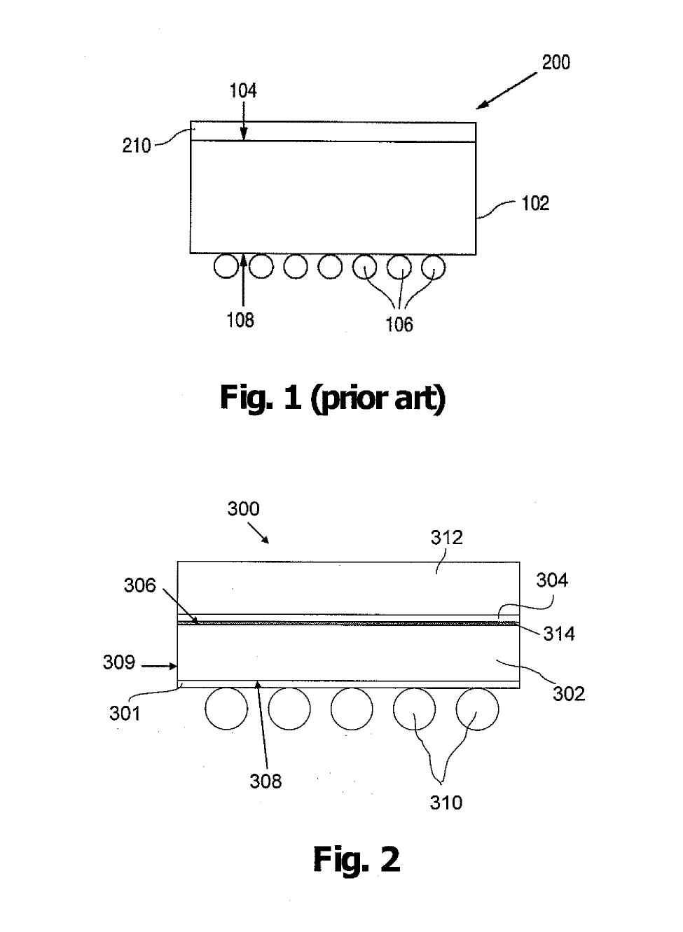

### DESCRIPTION OF THE PREFERRED EMBODIMENT

In the following description, numerous specific details are provided in order to give a through understanding of embodiments of the invention. Referring now to the following description wherein the description is for the purpose of illustrating the preferred embodiments of the present invention only, and not for the purpose of limiting the same. One skilled in the relevant art will recognize, however, that the invention may be practiced without one or more of the specific details, or with other methods, components, materials, etc.

FIG. 2 illustrates a cross-section diagram of a structure of semiconductor device package 300 according to the present invention. The package 300 comprises at least one die 302 having a back surface 306 and an active surface 308. It should be noted that the active surface 308 may includes contact pads 310 and a redistribution layer (RDL) 301 formed over the die 302. A plurality of contact pads or bumps 310 are formed on the active surface 308 of the die 302 for electrically connection. Namely, the adhesive layer 304 is formed on the back surface of the die 302. The protection substrate 312 is then formed on the adhesive layer 304. In one embodiment, the top surface of the protection substrate is employed as a laser or ink marking area.

In one embodiment, the material of the adhesive layer 304 includes elastic type material having elastic property to absorb the external force and/or acting the buffer layer. The material of the protection substrate 312 includes the build in fiber glass having rigid property to protect the package structure. The material of the protection substrate 312 preferably includes BT, FR5 or FR4. Please be noted that the build in fiber glass may enhance the strength of the protection substrate 312 but with thinner thickness, thereby scaling down the thickness of whole package.

In one embodiment, the thickness of the protection substrate 312 is approximately 50-200 μm. Preferably, the thickness of the protection substrate 312 can be 50, 100 or 200 μm. In the application, the thickness of the protection substrate 312 is substantially as near as the thickness of the die 302. The coefficient of thermal expansion (CTE) of the protection substrate 312 is about 14-17, and is preferably matching with the CTE of the printed circuit board (PCB) during the process.

Under the above structure, the package 300 comprises a protection substrate 312 with the build in fiber glass formed on the adhesive layer 304 to cover and protect the die 302 due to the substrate has the rigid character. The external force caused between the protection substrate 312 and the die 302 can be absorbed and buffered by the adhesive layer 304 due to the elastic property. It may absorb the external force promptly. Especially, the external forces at the lateral sides 309 can be reduced in the thinner package structure, such as the package size is 50-200 μm, and preferably, the size is about 100-300 μm for the Wafer Level-Chip Scale Package (WL-CSP) process.

According to another aspect of the invention, the present invention further provides a method for forming a semiconductor device package.

First, a plurality of die 302 is provided on a wafer, and each die 302 has a back side surface 306 and an active surface 308. The adhesive layer 304 is formed on the back surface 306 of the die 302. The protection substrate 312 is formed on the adhesive layer 304.

Sequentially, a plurality of bumps 310 are formed on the active surface 308 of the die 302, and the bumps 310 are employed for electrical connection. The plurality of die 302 is diced into individual die for singulation.

In one embodiment, the protection substrate 312 is formed by performing a panel bonding (lamination) method.

The scribe line (not shown) is disposed between each die 302, and the plurality of die 302 is separated into individual die for singulation along the scribe line. In one embodiment a conventional sawing blade is used during the singulation process. The blade is aligned to the scribe line to separate the dice into individual die during the singulation process.

The back side structure acts as a protection scheme in the present invention, it can prevent the package from being crack or warp, thereby protecting the package structure to increase the packaging yield and quality.

Optionally, a seed metal film (or layer) 314 can be sputtered or plated on the back side of the die 302 for better thermal management inquiry.

In the specification, it is appreciated that the certain descriptions regarding the similar elements are omitted to avoid obscuring the present invention. It is noted that the material and the arrangement of the structure are illustrated to describe but not to limit the present invention. The material and the arrangement of the structure can be modified according to the requirements of different conductions.

According to the aspect of the present invention, the present invention provides a structure of semiconductor device having a back side protection scheme that can protect the package structure during process to lower the costs and improve the reliability. The present invention also provides a new structure and method having no crack or warp issue after forming the protection substrate. Therefore, the chip scale package structure disclosed by the present invention can provide unexpected effect than prior art, and solve the problems of prior art. The structure may apply to wafer or panel industry and also can be applied and modified to other related applications.

As will be understood by a person skilled in the art, the foregoing preferred embodiments of the present invention are illustrative of the present invention, rather than limiting the present invention. Having described the invention in connection with a preferred embodiment, modification will suggest itself to those skilled in the art. Thus, the invention is not to be limited by this embodiment. Rather, the invention is intended to cover various modifications and similar arrangements included within the spirit and scope of the appended claims, the scope of which should be accorded the broadest interpretation so as to encompass all such modifications and similar structures.

Having described the invention, the following is claimed:

1. A structure of semiconductor device package, comprising:
a die having a back surface and an active surface formed thereon;
an adhesive layer formed on said back surface of said die;
a protection substrate formed on said adhesive layer; and
a plurality of bumps formed on said active surface of said die for electrically connection.

2. The structure in claim 1, wherein the material of said adhesive layer includes elastic type material.

3. The structure in claim 1, wherein the material of said protection substrate includes BT, FR5 or FR4.

4. The structure in claim 3, wherein the material of said protection substrate includes build in fiber glass formed therein.

5. The structure in claim 1, wherein the thickness of said protection substrate is approximately 50-200 μm.

6. The structure in claim 1, further comprising laser or ink marks formed on the top surface of said protection substrate.

7. The structure in claim 1, further comprising a redistribution layer (RDL) formed on said active surface of said die.

8. The structure in claim 1, further comprising a seed metal layer formed on said back surface of said die.

9. A method for forming a semiconductor device package, comprising: providing a plurality of die having a back surface and an active surface on a wafer;
forming an adhesive layer on said back surface of said die;
forming a protection substrates on said adhesive layer;
forming a plurality of bumps on said active surface of each die; and
dicing said plurality of die into individual die for singulation.

10. The method in claim 9, further comprising a step of sputtering a seed metal layer on said back surface of said die.

11. The method in claim 9, wherein said step of forming protection substrate is performed by panel bonding method.

12. The method in claim 9, wherein said step of dicing said plurality of die is performed by a sawing blade.

13. The method in claim 9, further comprising a step of forming laser or ink marks on the top surface of said protection substrate.
